(19) United States
(12) Patent Application Publication
(10) Pub. No.: US 2019/0278272 A1
(43) Pub. Date: Sep. 12, 2019

(54) METHOD, DEVICE, AND SYSTEM FOR OBJECT TESTING

(71) Applicant: SZ DJI TECHNOLOGY CO., LTD., Shenzhen (CN)

(72) Inventors: Kaiyong ZHAO, Shenzhen (CN); Shizhen ZHENG, Shenzhen (CN)

(21) Appl. No.: 16/421,711

(22) Filed: May 24, 2019

Related U.S. Application Data
(63) Continuation of application No. PCT/CN2016/107895, filed on Nov. 30, 2016.

(51) Int. Cl. G05D 1/00; G01M 17/00; G05D 1/02

(52) U.S. Cl. CPC G05D 1/0088; G05D 1/0231; G01M 17/00

(57) ABSTRACT

A method for testing an object to be tested includes obtaining a planned parameter corresponding to the object to be tested. The method also includes obtaining an actual parameter corresponding to the object to be tested through a simulation platform. The method further includes obtaining a testing result corresponding to the object to be tested based on the planned parameter and the actual parameter.

### CROSS-REFERENCE TO RELATED APPLICATION

This application is a continuation application of International Application No. PCT/CN2016/107895, filed on Nov. 30, 2016, the entire content of which is incorporated herein by reference.

### TECHNICAL FIELD

The present disclosure relates to the technology field of unmanned vehicle and, more particularly, to a method, a device, and a system for object testing.

### BACKGROUND

As technologies advance, unmanned vehicles have been widely deployed in various technical fields. The unmanned vehicles may include a robot, an unmanned aircraft, an unmanned car, an unmanned boat or ship, etc.

In conventional technologies, an unmanned vehicle may be controlled by a pre-installed or pre-set object (e.g., an algorithm). When developing the unmanned vehicle, it is necessary to test the object that controls the unmanned vehicle for one or more times, to ensure the correctness and stability of the object. In conventional technologies, the object is first developed. After the object is developed, the object is written or programmed into the unmanned vehicle. A physical testing environment is established, and the unmanned vehicle is operated in the physical testing environment. A tester may observe the operating status of the unmanned vehicle to determine whether the object is correct.

However, in the current technologies, it is difficult to assess the correctness and stability of the object through human observation. Therefore, the accuracy of the object testing is often low.

### SUMMARY

In accordance with an aspect of the present disclosure, there is provided a method for testing an object to be tested. The method includes obtaining a planned parameter corresponding to the object to be tested. The method also includes obtaining an actual parameter corresponding to the object to be tested through a simulation platform. The method further includes obtaining a testing result corresponding to the object to be tested based on the planned parameter and the actual parameter.

In accordance with another aspect of the present disclosure, there is also provided a device for testing an object to be tested. The device includes a first acquisition apparatus configured to obtain a planned parameter corresponding to the object to be tested. The device also includes a second acquisition apparatus configured to obtain an actual parameter corresponding to the object to be tested through a simulation platform. The device further includes a testing apparatus configured to determine a testing result corresponding to the object to be tested based on the planned parameter and the actual parameter.

In accordance with another aspect of the present disclosure, there is also provided a system for testing an object to be tested. The system includes a storage device configured to store instructions. The system also includes a processor configured to retrieve the instructions and execute the instructions to obtain a planned parameter corresponding to the object to be tested. The processor is also configured to obtain an actual parameter corresponding to the object to be tested through a simulation platform. The processor is further configured to determine a testing result corresponding to the object to be tested based on the planned parameter and the actual parameter.

According to the present disclosure, when an object is to be tested, a planned parameter corresponding to the object to be tested may be obtained. An actual parameter of the object to be tested may be obtained through a simulation platform. A testing result corresponding to the object to be tested may be determined based on the planned parameter and the actual parameter. During the testing process, no physical testing environment needs to be established. The actual parameter of the object to be tested may be obtained through the simulation platform, thereby increasing the efficiency of obtaining the actual parameter. Further, the testing result may be obtained based on the planned parameter and the actual parameter through the simulation platform. There is no need to rely on a human to observe and assess the testing, thereby increasing the accuracy of object testing.

### BRIEF DESCRIPTION OF THE DRAWINGS

To better describe the technical solutions of the various embodiments of the present disclosure, the accompanying drawings showing the various embodiments will be briefly described. As a person of ordinary skill in the art would appreciate, the drawings show only some embodiments of the present disclosure. Without departing from the scope of the present disclosure, those having ordinary skills in the art could derive other embodiments and drawings based on the disclosed drawings without inventive efforts.

FIG. 1 is a schematic illustration of an application scene of an object testing method, according to an example embodiment.

FIG. 2 is a flow chart illustrating a method for object testing, according to an example embodiment.

FIG. 3 is a schematic illustration of a testing model, according to an example embodiment.

FIG. 4 is a flow chart illustrating a method for obtaining a planned parameter, according to an example embodiment.

FIG. 5 is a flow chart illustrating a method for obtaining an actual parameter, according to an example embodiment.

FIG. 6 is a schematic illustration of a planned path and an actual path, according to an example embodiment.

FIG. 7 is a schematic illustration of a testing model, according to another example embodiment.

FIG. 8 is a flow chart illustrating a method for obtaining a planned parameter, according to another example embodiment.

FIG. 9 is a flow chart illustrating a method for obtaining an actual parameter, according to another example embodiment.

FIG. 10 is a schematic illustration of a testing model, according to another example embodiment.

FIG. 11 is a flow chart illustrating a method for obtaining a planned parameter, according to another example embodiment.

FIG. 12 is a flow chart illustrating a method for obtaining an actual parameter, according to another example embodiment.

FIG. 13 is a flow chart illustrating a method for determining a testing result, according to an example embodiment.

FIG. 14 is a flow chart illustrating a method for testing a planned parameter, according to another example embodiment.

FIG. 15 is a schematic illustration of interfaces showing a standard path and a planned path, according to an example embodiment.

FIG. 16 is a schematic illustration of an object testing device, according to an example embodiment.

FIG. 17 is a schematic illustration of an object testing device, according to another example embodiment.

FIG. 18 is a schematic illustration of an object testing system, according to an example embodiment.

FIG. 19 is a schematic illustration of an object testing system, according to another example embodiment.

### DETAILED DESCRIPTION OF THE EMBODIMENTS

Technical solutions of the present disclosure will be described in detail with reference to the drawings, in which the same numbers refer to the same or similar elements unless otherwise specified. It will be appreciated that the described embodiments represent some, rather than all, of the embodiments of the present disclosure. Other embodiments conceived or derived by those having ordinary skills in the art based on the described embodiments without inventive efforts should fall within the scope of the present disclosure.

As used herein, when a first component (or unit, element, member, part, piece) is referred to as “coupled,” “mounted,” “fixed,” “secured” to or with a second component, it is intended that the first component may be directly coupled, mounted, fixed, or secured to or with the second component, or may be indirectly coupled, mounted, or fixed to or with the second component via another intermediate component. The terms “coupled,” “mounted,” “fixed,” and “secured” do not necessarily imply that a first component is permanently coupled with a second component. The first component may be detachably coupled with the second component when these terms are used. When a first component is referred to as “connected” to or with a second component, it is intended that the first component may be directly connected to or with the second component or may be indirectly connected to or with the second component via an intermediate component. The connection may include mechanical and/or electrical connections. The connection may be permanent or detachable. The electrical connection may be wired or wireless.

When a first component is referred to as “disposed,” “located,” or “provided” on a second component, the first component may be directly disposed, located, or provided on the second component or may be indirectly disposed, located, or provided on the second component via an intermediate component. The term “on” does not necessarily mean that the first component is located higher than the second component. In some situations, the first component may be located higher than the second component. In some situations, the first component may be disposed, located, or provided on the second component, and located lower than the second component. In addition, when the first item is disposed, located, or provided “on” the second component, the term “on” does not necessarily imply that the first component is fixed to the second component. The connection between the first component and the second component may be any suitable form, such as secured connection (fixed connection) or movable contact.

When a first component is referred to as “disposed,” “located,” or “provided” in a second component, the first component may be partially or entirely disposed, located, or provided in, inside, or within the second component. When a first component is coupled, secured, fixed, or mounted “to” a second component, the first component may be is coupled, secured, fixed, or mounted to the second component from any suitable directions, such as from above the second component, from below the second component, from the left side of the second component, or from the right side of the second component.

The terms “perpendicular,” “horizontal,” “left,” “right,” “up,” “upward,” “upwardly,” “down,” “downward,” “downwardly,” and similar expressions used herein are merely intended for description.

Unless otherwise defined, all the technical and scientific terms used herein have the same or similar meanings as generally understood by one of ordinary skill in the art. As described herein, the terms used in the specification of the present disclosure are intended to describe example embodiments, instead of limiting the present disclosure.

In addition, the singular forms “a,” “an,” and “the” are intended to include the plural forms as well, unless the context indicates otherwise. And, the terms “comprise,” “comprising,” “include,” and the like specify the presence of stated features, steps, operations, elements, and/or components but do not preclude the presence or addition of one or more other features, steps, operations, elements, components, and/or groups. The term “and/or” used herein includes any suitable combination of one or more related items listed. For example, A and/or B can mean A only, A and B, and B only. The symbol “/” means “or” between the related items separated by the symbol. The phrase “at least one of” A, B, or C encompasses all combinations of A, B, and C, such as A only, B only, C only, A and B, B and C, A and C, and A, B, and C. In this regard, A and/or B can mean at least one of A or B.

The term “unmanned vehicle” refers to a physical, real unmanned vehicle, unless it is modified by the word “virtual.” A “virtual unmanned vehicle” refers to a simulated unmanned vehicle generated by a simulation algorithm or device, such as a simulation platform.

Further, when an embodiment illustrated in a drawing shows a single element, it is understood that the embodiment may include a plurality of such elements. Likewise, when an embodiment illustrated in a drawing shows a plurality of such elements, it is understood that the embodiment may include only one such element. The number of elements illustrated in the drawing is for illustration purposes only, and should not be construed as limiting the scope of the embodiment. Moreover, unless otherwise noted, the embodiments shown in the drawings are not mutually exclusive, and they may be combined in any suitable manner. For example, elements shown in one embodiment but not another embodiment may nevertheless be included in the other embodiment.

The following descriptions explain example embodiments of the present disclosure, with reference to the accompanying drawings. Unless otherwise noted as having an obvious conflict, the embodiments or features included in various embodiments may be combined.

The following embodiments do not limit the sequence of execution of the steps included in the disclosed methods. The sequence of the steps may be any suitable sequence, and certain steps may be repeated.

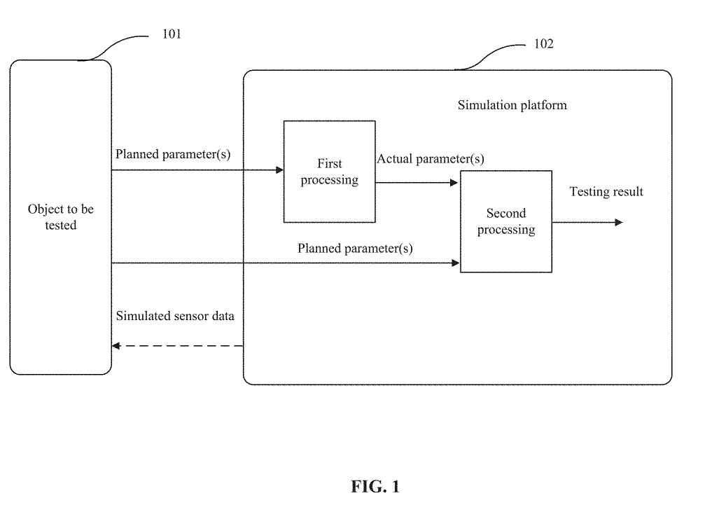

FIG. 1 is a schematic illustration of an application scene of an object testing method. The scene includes an object 101 to be tested (or target object, testing object), and a simulation platform 102. The simulation platform 102 may be configured to obtain simulated sensor data, and process the simulated sensor data through the object 101 to be tested to obtain a planned parameter. In some embodiments, the simulation platform 102 may be configured to process the planned parameter and an actual parameter to generate a testing result corresponding to the object 101 to be tested. The object 101 may be software, hardware, or a combination thereof. The object 101 to be tested may include at least one of an algorithm or a physical part, etc. In some embodiments, an object to be tested may be part of or include a vehicle. For example, the object to be tested may be provided in an unmanned vehicle, provided in a pre-set virtual model, or provided in the simulation platform. According to the present disclosure, no physical testing environment needs to be established. The planned parameter and the actual parameter for testing the object to be tested may be obtained in real time through the simulation platform, thereby improving the efficiency of obtaining the planned parameter and the actual parameter. In some embodiments, the disclosed method may include processing, in real time, the actual parameter and the planned parameter to obtain, in real time, a testing result corresponding to the object to be tested, thereby increasing the efficiency of determining a testing result. In some embodiments, the testing result obtained by the simulation platform based on the planned parameter and the actual parameter is more accurate, thereby increasing the accuracy of testing the object. It should be understood that more than one parameter (e.g., more than one planned parameter and/or actual parameter) may be used.

Next, the technical solutions of the present disclosure will be explained through specific embodiments. The embodiments of the present disclosure can be combined. Descriptions are not repeated for similar or the same features or processes.

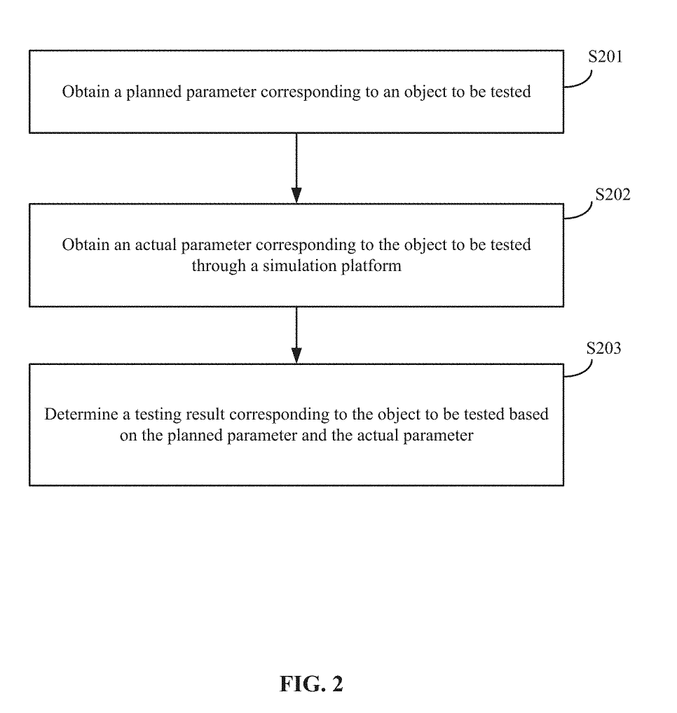

FIG. 2 is a flow chart illustrating a method for testing an object. The method of FIG. 2 may include:

Step S201: obtaining a planned parameter corresponding to an object to be tested.

Step S202: obtaining an actual parameter corresponding to the object to be tested through a simulation platform.

Step S203: determining a testing result corresponding to the object to be tested based on the planned parameter and the actual parameter.

The entity for performing the disclosed methods may be an object testing device (or testing device). The testing device may include hardware and/or software. The testing device may be provided in the simulation platform. In some embodiments, the testing device may be the simulation platform or may be part of the simulation platform.

In some embodiments, the object to be tested may be a part of the unmanned vehicle. The unmanned vehicle may include at least one of a robot, an unmanned aircraft, an unmanned car, an unmanned boat or ship, etc. The object to be tested may include at least one of an algorithm for controlling the unmanned vehicle, or a physical part of the unmanned vehicle.

In some embodiments, when the testing device tests the object to be tested, the testing device may obtain a planned parameter corresponding to the object to be tested. For example, the planned parameter may include at least one of a planned path, a planned status (e.g., a planned velocity (including a planned angular velocity), a planned acceleration, or a planned attitude, etc.), a planned distance, or a planned location (e.g., planned three-dimensional coordinates (x, y, z) of the unmanned vehicle), etc. In some embodiments, the planned parameter may be a parameter determined based on the object to be tested. It is noted that the term “velocity” includes linear velocity and angular velocity. The term “acceleration” includes linear acceleration and angular acceleration.

In some embodiments, the testing device may obtain an actual parameter corresponding to the object to be tested through the simulation platform. The actual parameter may include at least one of an actual path, an actual status (e.g., an actual velocity (including an actual angular velocity), an actual acceleration, or an actual attitude, etc.), an actual distance, or an actual location (e.g., actual coordinates (x, y, z) of the unmanned vehicle), etc. In some embodiments, the actual parameter may be a parameter obtained through processing the planned parameter. For example, the testing device may process the planned parameter to obtain a control command (e.g., a rotating speed and/or a rotating direction of an electric motor) for controlling the unmanned vehicle, and may generate the actual parameter based on the control command.

For example, assuming that the object to be tested includes at least one of a vision algorithm, a path planning algorithm, a sensor fusion algorithm, or a control algorithm, and assuming that the planned parameter includes a planned path, and the actual parameter includes an actual path, the testing device may obtain a planned path by processing the sensor data using the vision algorithm and/or the path planning algorithm. The testing device may also process the planned path using the control algorithm to obtain a control command (e.g., the rotating speed of and/or the rotating direction of the electric motor) for controlling the unmanned vehicle. The testing device may obtain the actual path based on the control command.

In some embodiments, after the testing device obtains the planned parameter and the actual parameter corresponding to the object to be tested, the testing device may determine a testing result corresponding to the object to be tested based on the planned parameter and the actual parameter. In some embodiments, the testing device may compare the planned parameter and the actual parameter to obtain the testing result corresponding to the object to be tested. The testing device may determine whether the object to be tested is in a normal state or in an abnormal state based on the testing result.

In some embodiments, when the object to be tested is tested, the testing device may obtain the planned parameter corresponding to the object to be tested. The testing device may obtain the actual parameter corresponding to the object to be tested through the simulation platform. The testing device may determine the testing result corresponding to the object to be tested based on the planned parameter and the actual parameter. In the testing process, there is no need to establish a physical testing environment. The planned parameter and the actual parameter for testing the object to be tested may be obtained in real time through the simulation platform, thereby increasing the efficiency of obtaining the planned parameter and the actual parameter. The testing device may also process, in real time, the actual parameter and the planned parameter to obtain, in real time, the testing result corresponding to the object to be tested, thereby increasing the efficiency of determining the testing result. The testing result obtained based on the planned parameter and the actual parameter through the simulation platform is more accurate. Thus, the accuracy of object testing is improved.

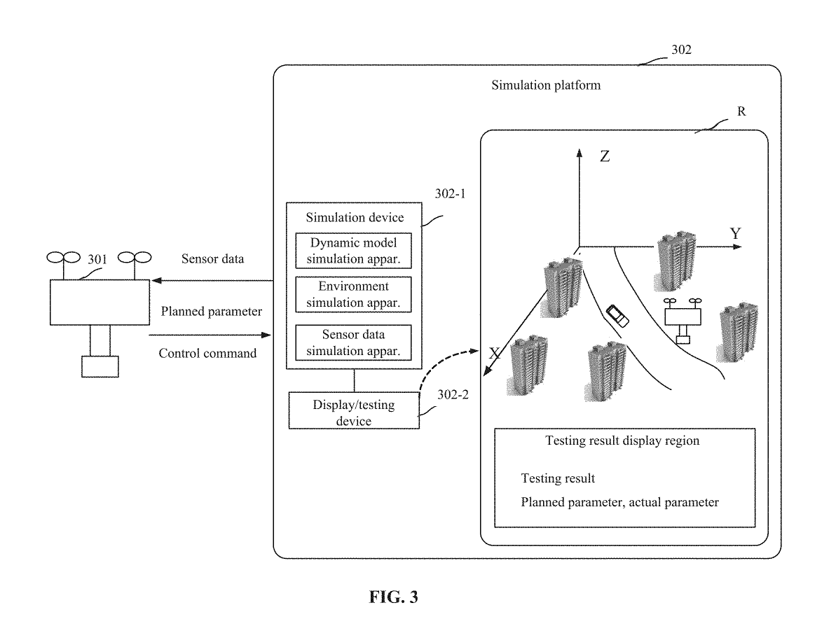

Based on the embodiment of FIG. 2, the object to be tested may be tested using various types of testing models. Different testing models may generate different planned parameters and actual parameters corresponding to the object to be tested. Next, through the embodiments shown in FIG. 3-FIG. 12, three testing models are introduced. The processes for obtaining the planned parameter and the actual parameter corresponding to the object to be tested using various types of testing models are described.

FIG. 3 is a schematic illustration of a testing model. As shown in FIG. 3, the testing model includes an unmanned vehicle 301 and a simulation platform 302.

The unmanned vehicle 301 may be provided with a first pre-set object and a second pre-set object. The object to be tested may include the first pre-set object and/or the second pre-set object (e.g., at least one of the first pre-set object or the second pre-set object). The first and/or second pre-set object may be software and/or hardware that may be installed, loaded, or mounted to the UAV. For example, the first and/or second pre-set object may include a firmware update, a hardware device such as a sensor, etc. In some embodiments, the first and/or second pre-set object may include a pre-set vision algorithm, a pre-set path planning algorithm, a pre-set sensor fusion algorithm, or a pre-set control algorithm. In some embodiments, the first and/or second pre-set object may include an already installed sensor (e.g., an inertial measurement unit, a gyroscope, a radar, etc.) included in the UAV. In some embodiments, an object to be tested may include a UAV, a group of UAVs, a part of a UAV. In some embodiments, the object to be tested may include software (e.g., an algorithm), hardware (e.g., a sensor), or a combination thereof. It is understood that the present disclosure does not limit the type of object to be tested. The object to be tested may be other vehicles or objects, such as robots, aircrafts, ships, boats, submarines, ground vehicles, etc.

The simulation platform 302 may include a simulation device 302-1 and a display/testing device 302-2.

The simulation device 302-1 may include at least one of an unmanned vehicle dynamic model simulation apparatus, an environment simulation apparatus, or a sensor data simulation apparatus. The unmanned vehicle dynamic model simulation apparatus may be configured to simulate the unmanned vehicle that is connected with the simulation platform (hence may generate a virtual unmanned vehicle). The environment simulation apparatus may be configured to simulate a virtual scene in the simulation platform. The sensor data simulation apparatus may be configured to simulate sensor data based on status of the virtual unmanned vehicle simulated by the unmanned vehicle dynamic model simulation apparatus and based on the virtual scene.

In some embodiments, the display/testing device 302-2 may be configured to display, in a display region R on the simulation platform, the virtual unmanned vehicle simulated by the unmanned dynamic model simulation apparatus. The display/testing device 302-2 may also be configured to display the virtual scene generated by simulation performed by the environment simulation apparatus. The display/testing device 302-2 may also be configured to determine a testing result of the object to be tested, and to display, in a testing result display region in the region R, the testing result. For example, the display/testing device 302-2 may display, in the testing result display region in the region R, a planned parameter and an actual parameter.

In some embodiments, the sensor data simulation apparatus included in the simulation platform 302 may generate or obtain sensor data based on the status of the virtual unmanned vehicle (e.g., velocity and location of the virtual unmanned vehicle) simulated by the unmanned vehicle dynamic model simulation apparatus and based on the virtual scene. The sensor data simulation apparatus may be configured to transmit the sensor data to the real unmanned vehicle 301. The unmanned vehicle 301 may process the sensor data using a first pre-set object to obtain a planned parameter. In some embodiments, the unmanned vehicle 301 may process the planned parameter using a second pre-set object to obtain a control command. The unmanned vehicle 301 may transmit the planned parameter and the control command to the simulation platform 302, such that the simulation platform 302 may process the control command to obtain an actual parameter. In some embodiments, the first pre-set object and the second pre-sent object may be the same pre-set object, or different pre-set objects.

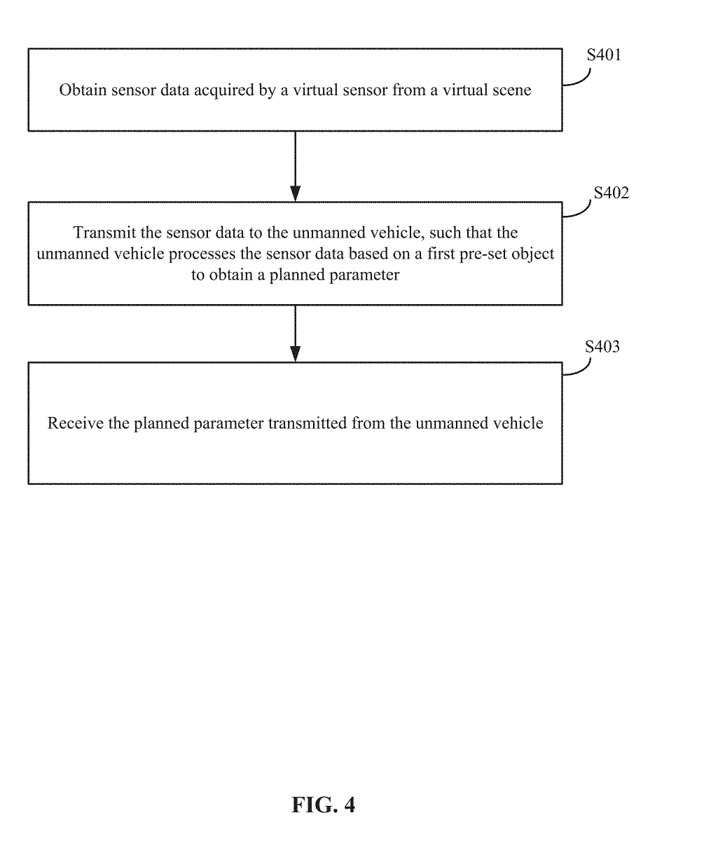

Based on the embodiment shown in FIG. 3, the following will explain in detail the process of obtaining the planned parameter using the testing model shown in FIG. 3 with reference to FIG. 4.

FIG. 4 is a flow chart illustrating a method for obtaining a planned parameter. The method of FIG. 4 may include:

Step S401: obtaining sensor data acquired by a virtual sensor from a virtual scene.

Step S402: transmitting the sensor data to the unmanned vehicle, such that the unmanned vehicle processes the sensor data based on a first pre-set object to obtain a planned parameter.

Step S403: receiving the planned parameter transmitted from the unmanned vehicle.

In some embodiments, when the object to be tested is tested using the testing model shown in FIG. 3, the unmanned vehicle may be provided with the first pre-set object and the second pre-set object (e.g., the object to be tested may include the first pre-set object and/or the second pre-set object). The environment simulation apparatus may create a virtual scene in the simulation platform. The unmanned vehicle dynamic model simulation apparatus may simulate an unmanned vehicle connected with the simulation platform (thereby generating a virtual unmanned vehicle). The unmanned vehicle that includes the object to be tested may be connected with the simulation platform, such that the unmanned vehicle and the simulation platform may communicate with one another.

In some embodiments, after the testing model starts the testing of the object to be tested, the testing device may obtain sensor data generated by the sensor data simulation apparatus based on the status of the virtual unmanned vehicle generated by the unmanned vehicle dynamic model simulation apparatus and based on the virtual scene. The testing device may transmit the sensor data to the unmanned vehicle (i.e., the real unmanned vehicle). In some embodiments, the sensor data may include at least one of the status of the virtual unmanned vehicle generated by the unmanned vehicle dynamic model simulation apparatus, a distance to an obstacle, or an image of a scene, etc.

In some embodiments, after the unmanned vehicle receives the sensor data, the unmanned vehicle may process the sensor data using the first pre-set object to obtain a planned parameter. The unmanned vehicle may transmit the planned parameter to the testing device. The first pre-set object may include at least one of a vision object and a path planning object. In some embodiments, the first pre-set object may include a first pre-set algorithm. Correspondingly, the vision object may be a computer vision algorithm, and the path planning object may be a path planning algorithm. In some embodiments, the computer vision algorithm may include a convolutional neural network (“CNN”) based computer vision algorithm, a Fast Fourier Transform (“FFT”) algorithm, a forward warping algorithm, etc. The first pre-set algorithm may include other suitable algorithms, such as an obstacle avoidance algorithm. In some embodiments, the obstacle avoidance algorithm may be part of the path planning algorithm. In some embodiments, the first pre-set algorithm may include a flight control algorithm, a navigation algorithm, a sensing algorithm.

In the above-described processes, the sensor data may be obtained by the sensor data simulation apparatus included in the simulation platform. The real unmanned vehicle may process the sensor data to obtain a planned parameter. As such, the planned parameter may be obtained without establishing a physical testing environment, thereby increasing the efficiency of obtaining the planned parameter.

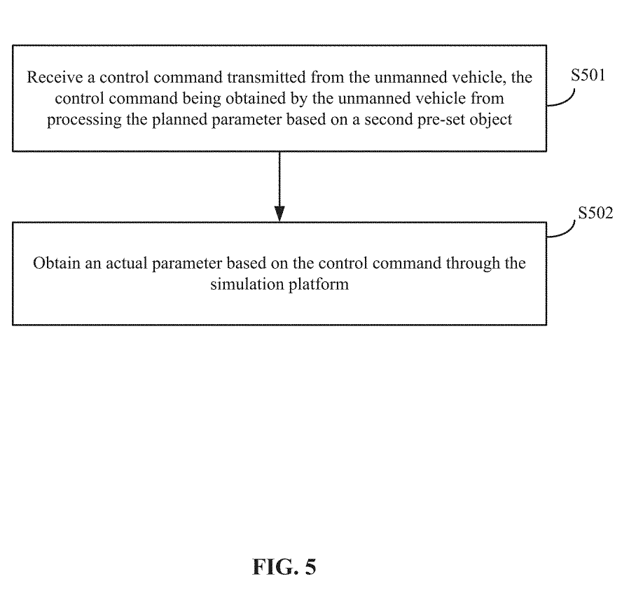

Based on the embodiments of FIG. 3 and FIG. 4, next, the process of obtaining an actual parameter will be explained with reference to FIG. 5.

FIG. 5 is a flow chart illustrating a method for obtaining an actual parameter. The method of FIG. 5 may include:

Step S501: receiving a control command transmitted from the unmanned vehicle, the control command being obtained by the unmanned vehicle from processing the planned parameter based on a second pre-set object.

Step S502: obtaining an actual parameter based on the control command through the simulation platform.

In some embodiments, after the unmanned vehicle obtains the planned parameter using the first pre-set object, the unmanned vehicle may also process the planned parameter using a second pre-set object to obtain a control command. The unmanned vehicle may transmit the control command to the testing device. The second pre-set object may include a control object. For example, when the second pre-set object includes a pre-set algorithm, the control object may include a control algorithm. In some embodiments, when the control command includes at least one of a rotating speed or a rotating direction of an electric motor included in the unmanned vehicle, correspondingly, the unmanned vehicle may obtain the control command through the following method: the unmanned vehicle may obtain a type of the planned parameter, and determine at least one electric motor corresponding to the planned parameter based on the type of the planned parameter. The unmanned vehicle may determine the rotating speed and/or the rotating direction of the electric motor based on the planned parameter.

In some embodiments, after the testing device obtains the control command, the testing device may obtain the actual parameter based on the control command through the simulation platform. In some embodiments, the testing device may obtain the actual parameter based on the rotating speed and/or rotating direction of each electric motor and other operating parameters of each electric motor.

In some embodiments, after the testing model starts operating, the virtual sensor included in the virtual unmanned vehicle simulated by the unmanned vehicle dynamic model simulation apparatus may acquire sensor data in real time. The testing device may obtain the sensor data acquired by the virtual sensor, and may transmit, in real time, the sensor data to the real unmanned vehicle. The unmanned vehicle may obtain the planned parameter in real time based on the sensor data, and obtain the actual parameter in real time based on the planned parameter.

Next, the methods of FIG. 4 and FIG. 5 will be described using specific examples.

For illustration purposes, the first pre-set object is assumed to include a vision algorithm and a path planning algorithm. The second pre-set object is assumed to include a control algorithm. The object to be tested is assumed to be any of the vision algorithm, the path planning algorithm, or the control algorithm, or any combination thereof.

In some embodiments, after the testing model shown in FIG. 3 starts operating, the virtual unmanned vehicle simulated by the unmanned vehicle dynamic model simulation apparatus may acquire data from the virtual scene using the virtual sensor included in the virtual unmanned vehicle. The testing device may obtain the sensor data acquired by the virtual sensor, and may transmit the sensor data to the real unmanned vehicle. For illustration purposes, the sensor data are assumed to include a velocity (v), an acceleration (A), and a moving direction (direction 1) of a virtual unmanned vehicle simulated by the unmanned vehicle dynamic model simulation apparatus, images of the surrounding environment (image 1-image N), and a distance to an obstacle (H).

In some embodiments, after the unmanned vehicle receives the sensor data transmitted from the testing device, the unmanned vehicle may process image 1-image N using the vision algorithm to determine a dimension of the obstacle (e.g., a length, width, and height of the obstacle), and a relative location (M0, N0) of the obstacle relative to the virtual unmanned vehicle simulated by the unmanned vehicle dynamic model simulation apparatus. The unmanned vehicle may process the dimension of the obstacle, the relative location (M0, N0) of the obstacle, and the velocity (v), acceleration (A), moving direction (direction 1) of the virtual unmanned vehicle, and the distance to the obstacle (H), to obtain a planned path. In some embodiments, the parameters used to calculate the planned path may include one or more of a parameter determined by the unmanned vehicle using the vision algorithm, and the sensor data transmitted by the simulation platform.

In some embodiments, the unmanned vehicle may process the planned path using the control algorithm to obtain the control command that may be used for controlling the rotating speed and/or the rotating direction of a corresponding electric motor (e.g., electric motor 1-electric motor 10) included in the unmanned vehicle. The unmanned vehicle may transmit the control command to the testing device.

In some embodiments, the testing device may determine an actual path corresponding to the object to be tested based on the control command. In some embodiments, the unmanned vehicle may also transmit the control command to the unmanned vehicle dynamic model simulation apparatus, such that the unmanned vehicle dynamic model simulation apparatus may control, based on the control command, the status (e.g., velocity, attitude, etc.) of the virtual unmanned vehicle simulated by the unmanned vehicle dynamic model simulation apparatus.

In some embodiments, based on the embodiments of FIG. 3-FIG. 5, the planned parameter and the actual parameter may be displayed in real time, such that a user may analyze the object to be tested based on the planned parameter and the actual parameter. In some embodiments, a historical parameter may be displayed, such that the user may analyze the object to be tested based on the planned parameter, the actual parameter, and the historical parameter. In some embodiments, each parameter may be updated in real time as the testing time passes.

In some embodiments, for the viewing convenience of the user, the testing device may display the actual parameter and the planned parameter in different colors. If the testing device determines that the testing result is abnormal, the testing device may identify the abnormal actual parameter using a predetermined color and/or a predetermined identification. In some embodiments, the testing device may analyze the actual parameter and the planned parameter to determine an abnormal object that causes the abnormal actual parameter. The testing device may indicate the abnormal object to the user, such that the user may locate the point of failure.

In some embodiments, the testing device may record the display process of displaying the actual parameter and the planned parameter in a recording document. For example, a video file may be saved that records the process of displaying the actual parameter and the planned parameter, such that the user may playback the recording document.

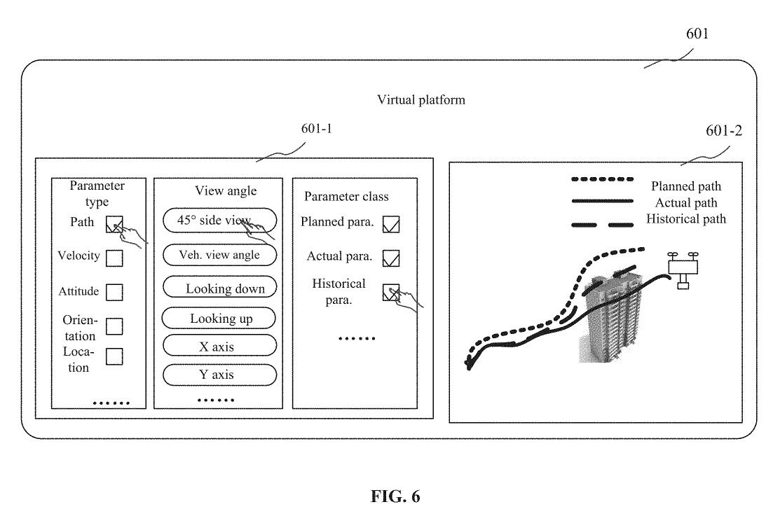

Next, the planned parameter, the actual parameter, and the display interface for displaying the planned parameter will be explained with reference to FIG. 6.

FIG. 6 is a display interface for displaying parameters. As shown in FIG. 6, the display interface may include a function selection region 601-1 and a parameter display region 601-2.

In some embodiments, the function selection region 601-1 may include multiple options (e.g., functions) for selection. For example, the function selection region may include a parameter type selection zone, a view angle selection zone, a parameter class selection zone, etc.

A user may select a parameter type, from the parameter type selection zone, to be displayed in the parameter display region 601-2. In some embodiments, the user may select multiple parameter types at the same time, such that parameters of the selected parameter types may be displayed in the parameter display region 601-2.

In some embodiments, the view angle selection zone may include multiple view angles, such as a 45 degree side view, an unmanned vehicle view angle (the “Veh. view angle” in FIG. 6), a looking down angle, a looking up angle, etc. When the parameter type includes a vision parameter type, such as a path type, a user may select different view angles, such that different vision parameters corresponding to different view angles may be displayed in the parameter display region 601-2.

In some embodiments, the parameter class selection zone may include a planned parameter, an actual parameter, a historical parameter. The user may select one or more of the three classes of parameters, such that parameters corresponding to the selected parameter classes may be displayed in the parameter display region 601-2.

In some embodiments, FIG. 6 shows only examples of the function selections that may be included in the function selection region 601-1. The function selection region 601-1 may include other types of function selections. The function selections to be included in the function selection region 601-1 may be determined based on actual needs.

The parameter display region 601-2 may display one or more parameters corresponding to the selected parameter type(s) and parameter class(es) in the selected view angle.

In some embodiments, FIG. 6 shows only an example display interface that may be used to display parameters of the simulation platform. The present disclosure does not limit the display interface to be the one shown in FIG. 6. The contents of the display interface and/or the process for displaying the parameters may be determined based on actual needs.

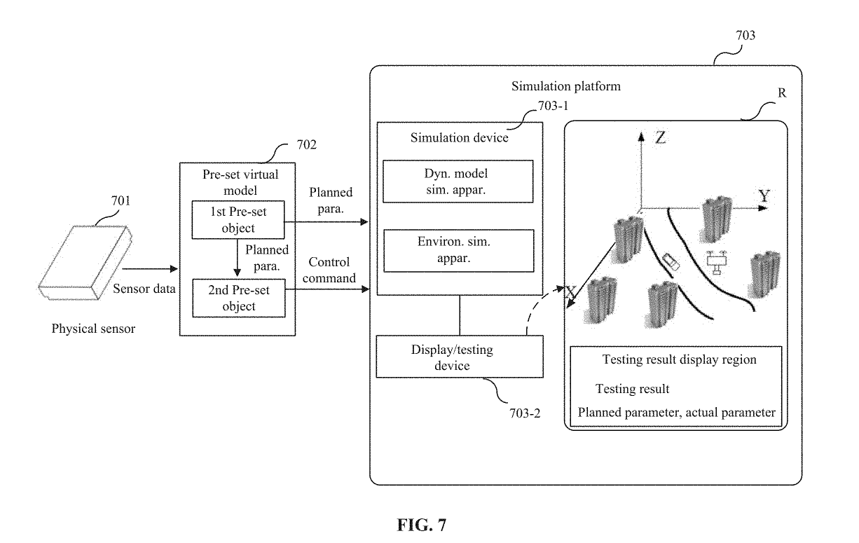

FIG. 7 is a schematic diagram of another testing model. As shown in FIG. 7, the testing model may include a physical sensor 701, a pre-set virtual model 702, and a simulation platform 703.

In some embodiments, the physical sensor 701 may be any physical sensor included in the real unmanned vehicle. In some embodiments, the physical sensor 701 may include at least one of an imaging device or an inertial measurement unit, etc. The physical sensor may include one sensor or an assembly of multiple sensors. In some embodiments, the physical sensor 701 may be replaced by a real unmanned vehicle (e.g., may be the real unmanned vehicle).

In some embodiments, the pre-set virtual model 702 may include a first pre-set object and a second pre-set object. The object to be tested may include the first pre-set object and/or the second pre-set object (e.g., at least one of the first pre-set object or the second pre-set object).

In some embodiments, the simulation platform 703 may include a simulation device 703 and a display/testing device 703-2. The simulation device 703-1 may include the unmanned vehicle dynamic model simulation apparatus and the environment simulation apparatus. The unmanned vehicle dynamic model simulation apparatus may be configured to simulate an unmanned vehicle (hence generating a virtual unmanned vehicle). The environment simulation apparatus may be configured to simulate a virtual scene in the simulation platform. The display/testing device 703-2 may be configured to display the virtual unmanned vehicle simulated by the unmanned vehicle dynamic model simulation apparatus in the display region R of the simulation platform. The display/testing device 703-2 may also display the virtual scene generated by the environment simulation apparatus. In some embodiments, the display/testing device 703-2 may be configured to determine a testing result corresponding to the object to be tested, and may display the testing result in the testing result display region of the display region R. In some embodiments, the display/testing device 703-2 may display the planned parameter and the actual parameter in real time.

In some embodiments, the physical sensor 701 may be operated in an actual physical environment to acquire sensor data from the actual physical environment. The physical sensor 701 may transmit the sensor data to the pre-set virtual model 702. The pre-set virtual model 702 may process the sensor data using a first pre-set object to obtain a planned parameter. The pre-set virtual model 702 may further process the planned parameter using a second pre-set object to obtain a control command. The pre-set virtual model 702 may transmit the planned parameter and the control command to the simulation platform 703.

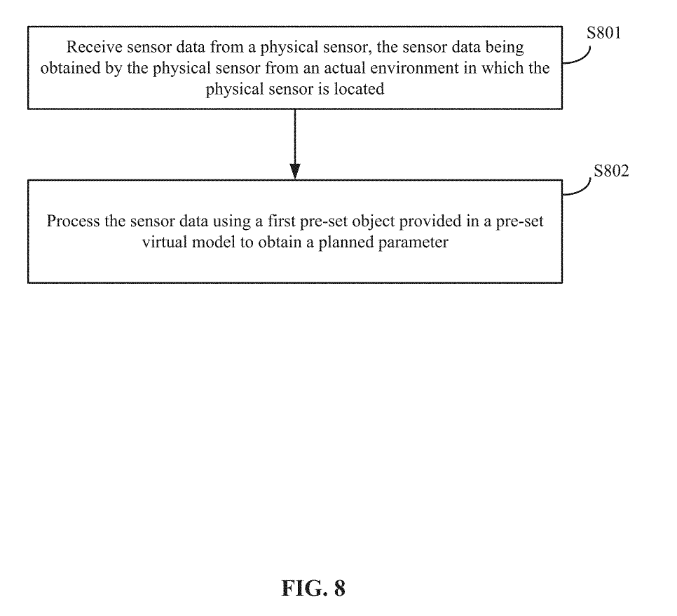

Based on the embodiment shown in FIG. 7, next, the process of obtaining the planned parameter using the testing model shown in FIG. 7 will be explained in detail with reference to FIG. 8.

FIG. 8 is a flow chart illustrating a method for obtaining a planned parameter. The method of FIG. 8 may include:

Step S801: receiving sensor data from a physical sensor, the sensor data being obtained by the physical sensor from an actual environment in which the physical sensor is located.

Step S802: processing the sensor data using a first pre-set object provided in a pre-set virtual model to obtain a planned parameter.

In some embodiments, the testing device may be provided in the pre-set virtual model and the simulation platform.

In some embodiments, to test the object to be tested using the testing model shown in FIG. 7, the pre-set virtual model may be provided with the first pre-set object and the second pre-set object (the object to be tested may include the first pre-set object and/or the second pre-set object). The environment simulation apparatus may generate a virtual scene in the simulation platform, and the unmanned vehicle dynamic model simulation apparatus may generate a virtual unmanned vehicle in the simulation platform. The physical sensor, the pre-set virtual model, and the simulation platform may be connected to communicate with one another.

In some embodiments, after the testing model starts the testing of the object to be tested, the physical sensor may be operated in an actual physical environment, and may acquire sensor data from the actual physical environment. The physical sensor may transmit the sensor data to the pre-set virtual model.

In some embodiments, the testing device may process the sensor data using the first pre-set object included in the pre-set virtual model to obtain the planned parameter. The first pre-set object of the present embodiment may be the same as the first pre-set object of the embodiment shown in FIG. 4. Thus, the descriptions of the first pre-set object of the present embodiment can refer to the descriptions of the first pre-set object of the embodiment shown in FIG. 4.

In the above-described process, the physical sensor may acquire sensor data, and the first pre-set object included in the pre-set virtual model may process the sensor data to obtain the planned parameter. Thus, the planned parameter may be obtained without establishing an actual physical testing environment, thereby increasing the efficiency of obtaining the planned parameter.

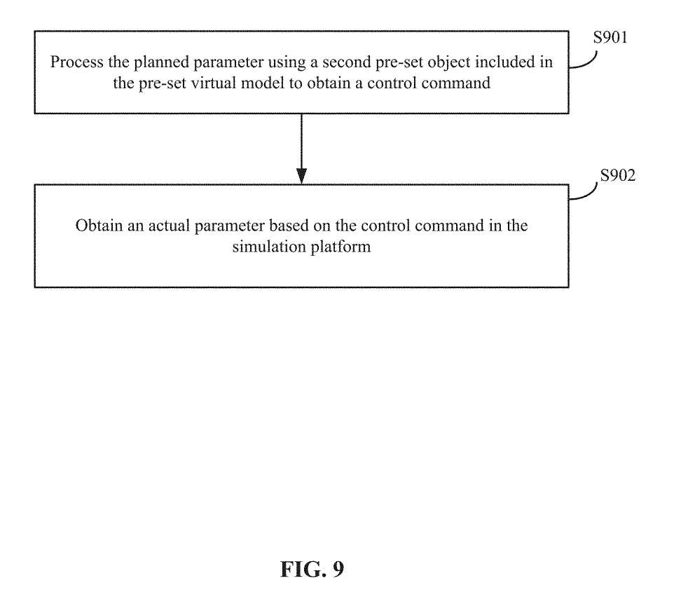

Next, based on the embodiments of FIG. 7 and FIG. 8, the process of obtaining an actual parameter will be explained in detail with reference to FIG. 9.

FIG. 9 is a flow chart illustrating another method for obtaining the actual parameter. The method of FIG. 9 may include:

Step S901: processing the planned parameter using a second pre-set object included in the pre-set virtual model to obtain a control command.

Step S902: obtaining an actual parameter based on the control command in the simulation platform.

In some embodiments, after the testing device obtains the planned parameter using the first pre-set object included in the pre-set virtual model, the testing device may further process the planned parameter using the second pre-set object included in the pre-set virtual model to obtain a control command. The second pre-set object of the present embodiment may be the same as the second pre-set object of the embodiment shown in FIG. 5. Thus, the descriptions of the second pre-set object of the present embodiment may refer to the descriptions of the second pre-set object of the embodiment shown in FIG. 5. The control command and the process of obtaining the control command in the embodiment of FIG. 9 may be the same as the control command and the process of obtaining the control command described above in connection with FIG. 5.

In some embodiments, after the testing device obtains the control command, the testing device may obtain the actual parameter through the simulation platform based on the control command. In some embodiments, the testing device may obtain the actual parameter based on the rotating speed and/or the rotating direction of each electric motor and other operating parameters of each electric motor.

In some embodiments, in the testing model shown in FIG. 7, the pre-set virtual model may be provided in the simulation platform. When the pre-set virtual model is provided in the simulation platform, the processes of obtaining the planned parameter and the actual parameter may be the same as those discussed above in connection with FIG. 8 and FIG. 9.

Next, the embodiments of FIG. 8 and FIG. 9 are further described using specific examples.

For illustration purposes, it is assumed that the first pre-set object includes a vision algorithm and a path planning algorithm. The second pre-set object includes a control algorithm. The object to be tested includes any one of the vision algorithm, the path planning algorithm, and the control algorithm, or any combination thereof.

After the testing model shown in FIG. 7 starts operation, the physical sensor may be operated in the actual physical environment (e.g., in a pre-set path or track). The physical sensor may acquire sensor data from the actual physical environment, and may transmit the sensor data to the pre-set virtual model. For illustration purposes, it is assumed that the sensor data include a velocity (v) and an acceleration (A) of the physical sensor, images of surrounding environment (e.g., image 1-image 10), and a distance to an obstacle (H).

In some embodiments, the testing device may process the images (e.g., image 1-image 10) using the vision algorithm of the pre-set virtual model to determine a dimension of the obstacle (e.g., a length, width, and height of the obstacle), and a relative location (M0, N0) of the obstacle relative to the virtual unmanned vehicle simulated by the unmanned vehicle dynamic model simulation apparatus. The testing device may process the dimension of the obstacle, the relative location (M0, N0) of the obstacle, the velocity (v), acceleration (A) of the unmanned vehicle, and the distance to the obstacle to obtain a planned path. Although two-dimensional coordinates (M0, N0) are used as an example to represent the relative location, it is understood that the relative location may be represented by three-dimensional coordinates, such as (M0, N0, Z0) corresponding to (x, y, z) in a three-dimensional coordinate system.

In some embodiments, the testing device may process the planned path using the control algorithm included in the pre-set virtual model, to obtain the control command for controlling the virtual unmanned vehicle that is generated by the unmanned vehicle dynamic model simulation apparatus.

In some embodiments, the testing device may determine the actual path corresponding to the object to be tested based on the control command. In some embodiments, the pre-set virtual model may transmit the control command to the unmanned vehicle dynamic model simulation apparatus, such that the unmanned vehicle dynamic model simulation apparatus may control, based on the control command, the status (e.g., velocity, attitude, etc.) of the virtual unmanned vehicle generated by the unmanned vehicle dynamic model simulation apparatus.

In some embodiments, based on the embodiments of FIG. 8 and FIG. 9, the planned parameter, the actual parameter, and the historical parameter may be displayed in real time. The display interface and the display process may be similar to the display interface and the display processed discussed above in connection with FIG. 6.

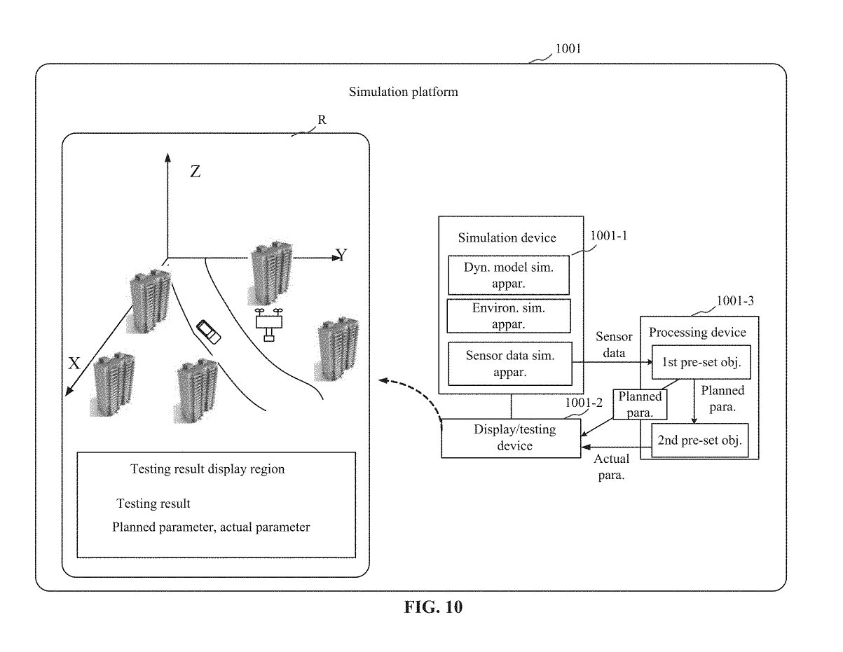

FIG. 10 is a schematic diagram of another testing model. The testing model shown in FIG. 10 may include a simulation platform 1001. The simulation platform 1001 may include a simulation device 1001-1, a display/testing device 1001-2, and a processing device 1001-3.

In some embodiments, the simulation device 1001-1 may include an unmanned vehicle dynamic model simulation apparatus, an environment simulation apparatus, and a sensor data simulation apparatus. The unmanned dynamic model simulation apparatus may be configured to simulate an unmanned vehicle (hence generating a virtual unmanned vehicle). The environment simulation apparatus may be configured to simulate a virtual scene of the simulation platform. The sensor data simulation apparatus may be configured to simulate sensor data based on the status of the virtual unmanned vehicle generated by the unmanned vehicle dynamic model simulation apparatus and based on the virtual scene.

In some embodiments, the display/testing device 1001-2 may display, in the display region R of the simulation platform, the virtual unmanned vehicle generated by the unmanned vehicle dynamic model simulation apparatus, and the virtual scene generated by the environment simulation apparatus. The display/testing device 1001-2 may also be configured to determine a testing result for the object to be tested. In some embodiments, the display/testing device 1001-2 may be configured to display the testing result, the planned parameter, and the actual parameter in a testing result display region of the display region R.

In some embodiments, the processing device 1001-3 may be configured to process, based on the first pre-set object, the sensor data obtained by the sensor data simulation apparatus to obtain the planned parameter. The processing device 1001-3 may also be configured to process, based on the second pre-set object, the planned parameter to obtain the actual parameter. The processing device 1001-3 may also transmit the planned parameter and the actual parameter to the display/testing device 1001-2, such that the display/testing device 1001-2 may determine a testing result based on the planned parameter and the actual parameter.

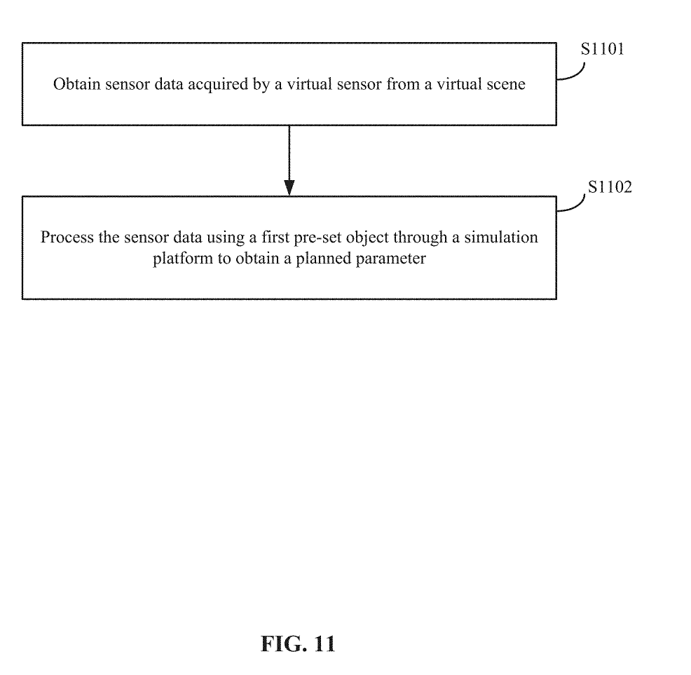

Based on the embodiments of FIG. 10, next, the process of obtaining the planned parameter in the testing model of FIG. 10 will be explained in detail with reference to FIG. 11.

FIG. 11 is a flow chart illustrating another method for obtaining the planned parameter. The method of FIG. 11 may include:

Step S1101: obtaining sensor data acquired by a virtual sensor from a virtual scene.

Step S1102: processing the sensor data using a first pre-set object through a simulation platform to obtain a planned parameter.

In some embodiments, when the object to be tested is tested using a fully virtual testing model, the environment simulation apparatus may establish a virtual scene in the simulation platform. The unmanned vehicle dynamic model simulation apparatus may simulate the unmanned vehicle in the simulation platform. The first pre-set object and the second pre-set object may be provided in the processing device of the simulation platform.

In some embodiments, after the testing model starts testing of the object to be tested, the testing device may obtain the sensor data obtained by the sensor data simulation apparatus based on the status of the virtual unmanned vehicle generated by the unmanned vehicle dynamic model simulation apparatus and based on the virtual scene. The testing device may process the sensor data based on the first pre-set object included in the simulation platform to obtain the planned parameter. The first pre-set object of this embodiment may be the same as the first pre-set object of the embodiment of FIG. 4.

In the above processes, sensor data may be obtained through the sensor data simulation apparatus of the simulation platform. The sensor data may be processed by the processing device of the simulation platform to obtain the planned parameter. As such, the planned parameter may be obtained without establishing an actual testing environment, thereby increasing the efficiency of obtaining the planned parameter.

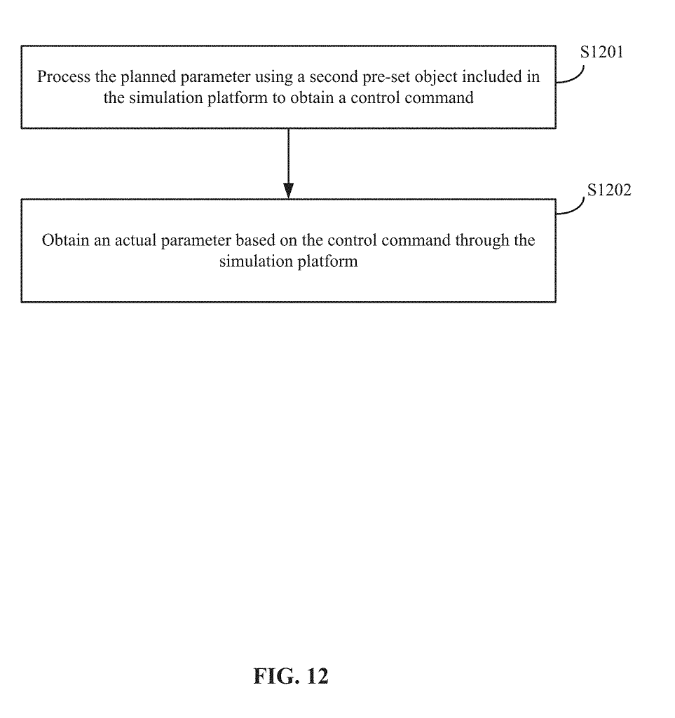

Based on the embodiments of FIG. 10 and FIG. 11, next, the process of obtaining the actual parameter will be explained in detail with reference to FIG. 12.

FIG. 12 is a flow chart illustrating another method for obtaining the actual parameter. The method of FIG. 12 may include:

Step S1201: processing the planned parameter using a second pre-set object included in the simulation platform to obtain a control command.

Step S1202: obtaining an actual parameter based on the control command through the simulation platform.

In some embodiments, after the testing device obtains the planned parameter using the first pre-set object in the simulation platform, the testing device may also process the planned parameter using the second pre-set object in the simulation platform to obtain the control command. The second pre-set object of this embodiment may be the same as the second pre-set object of the embodiment shown in FIG. 5. The control command and the process of obtaining the control command in this embodiment may be the same as the control command and the process of obtaining the control command in the embodiment shown in FIG. 5.

In some embodiments, after the testing device obtains the control command, the testing device may obtain the actual parameter based on the control command through the simulation platform. In some embodiments, the testing device may obtain the actual parameter based on the rotating speed and/or the rotating direction of each electric motor and other operating parameters of each electric motor.

Next, the methods of FIG. 11 and FIG. 12 are explained in detail through specific examples.

For illustration purposes, it is assumed that the first pre-set object includes a vision algorithm and a path planning algorithm. The second pre-set object includes a control algorithm. The object to be tested includes any one of the vision algorithm, the path planning algorithm, and the control algorithm, or any combination thereof.

In some embodiments, after the fully virtual testing model starts operating, the virtual unmanned vehicle generated by the unmanned vehicle dynamic model simulation apparatus may be operated in the virtual scene. The sensor data may be acquired by the virtual sensor from the virtual scene. It is also assumed that the sensor data include a velocity (v) and an acceleration (A) of the virtual unmanned vehicle generated by the unmanned vehicle dynamic model simulation apparatus, images of the surrounding environment (image 1-image 10), and a distance to an obstacle (H).

In some embodiments, the testing device may process image 1 based on the vision algorithm of the simulation platform to determine a dimension of the obstacle (e.g., a length, width, and height of the obstacle), and a relative location (M0, N0) of the obstacle relative to the virtual unmanned vehicle simulated by the unmanned vehicle dynamic model simulation apparatus. The testing device may process the dimension of the obstacle, the relative location (M0, N0) of the obstacle, the velocity (v) and acceleration (A) of the virtual unmanned vehicle, and the distance to the obstacle, to obtain a planned path.

In some embodiments, the testing device may process the planned path using the control algorithm of the simulation platform to obtain the rotating speed and rotating direction (collectively, the control command) of virtual electric motor 1-virtual electric motor 10 included in the virtual unmanned vehicle generated by the unmanned vehicle dynamic model simulation apparatus. The testing device may also determine, based on the rotating speed and rotating direction of the virtual electric motor 1-virtual electric motor 10, the actual path of the virtual unmanned vehicle generated by the unmanned vehicle dynamic model simulation apparatus. In some embodiments, the testing device may transmit the control command to the virtual unmanned vehicle generated by the unmanned vehicle dynamic model simulation apparatus, such that the unmanned vehicle dynamic model simulation apparatus may control the status of the virtual unmanned vehicle (e.g., velocity and attitude, etc.) based on the control command.

In some embodiments, based on the embodiments of FIG. 11 and FIG. 12, the planned parameter, the actual parameter, and the historical parameter may be displayed in real time. The display interface for displaying the parameters and the display processes may be similar to the display interface and the display processes described above in connection with FIG. 6.

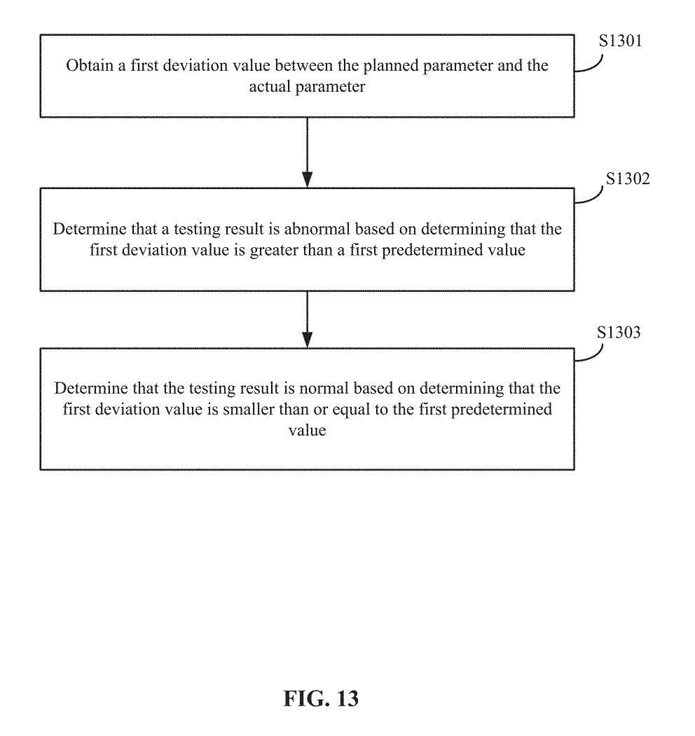

Based on any of the above embodiments, in some embodiments, the testing device may determine a testing result corresponding to the object to be tested based on the planned parameter and the actual parameter using at least one of the following methods. An example method is shown in FIG. 13.

FIG. 13 is a flow chart illustrating a method for determining a testing result. The method of FIG. 13 may include:

Step S1301: obtaining a first deviation value between the planned parameter and the actual parameter.

Step S1302: determining that a testing result is abnormal based on determining that the first deviation value is greater than a first predetermined value.

Step S1303: determining that the testing result is normal based on determining that the first deviation value is smaller than or equal to the first predetermined value.

In some embodiments, after the testing device obtains the planned parameter and the actual parameter, the testing device may obtain a first deviation value between the planned parameter and the actual parameter. The testing device may determine whether the first deviation value is greater than the first predetermined value. If the first deviation value is greater than the first predetermined value, the testing device may determine that the testing result is abnormal. If the first deviation value is not greater than the first predetermined value, the testing device may determine that the testing result is normal. In practical applications, the first predetermined value may be determined based on actual needs. In some embodiments, the first deviation value between the planned parameter and the actual parameter may be a difference between the planned parameter and the actual parameter at the same time instance. For example, if the planned parameter is a planned path, and the actual parameter is an actual path, then the first deviation value between the planned path and the actual path may be a distance between the planned path and the actual path at the same time instance. In some embodiments, the first deviation value between the planned parameter and the actual parameter may be a difference between an average value of the planned parameter and an average value of the actual parameter. For example, if the planned parameter is a planned speed, and the actual parameter is an actual speed, then the first deviation value between the planned speed and the actual speed may be the difference between the average value of the planned speed and the average value of the actual speed. In some embodiments, the first predetermined value may be a maximum allowable error.

In some embodiments, rules for determining the first deviation value may be determined based on actual needs. In addition, the first predetermined value may be set based on actual needs. The present disclosure does not limit the methods for determining the first deviation value and the first predetermined value.

In some embodiments, when the testing device determines the testing result based on the planned parameter and the actual parameter, the testing device may obtain at least one historical parameter corresponding to the object to be tested. The historical parameter may include a planned parameter and/or an actual parameter that are obtained prior to the present time instance during a previous testing of the object to be tested. Correspondingly, the testing device may determine the test result based on the planned parameter, the actual parameter, and the at least one historical parameter.

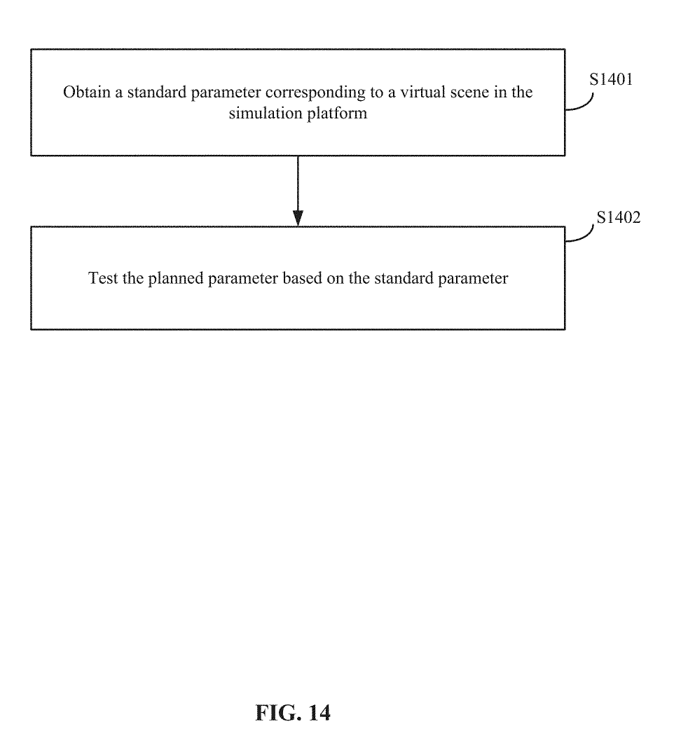

Based on any one of the above embodiments, after the testing device obtains the planned parameter corresponding to the object to be tested, the testing device may test the planned parameter to determine whether the planned parameter is normal. Next, the process of testing the planned parameter will be explained in detail with reference to FIG. 14.

FIG. 14 is a flow chart illustrating a method for testing a planned parameter. The method of FIG. 14 may include:

Step S1401: obtaining a standard parameter corresponding to a virtual scene in the simulation platform.

Step S1402: testing the planned parameter based on the standard parameter.

The method of FIG. 14 may be applied to any of the embodiments of the testing models shown in FIG. 3, FIG. 7, and FIG. 10.

In some embodiments, when the testing device tests the planned parameter, the testing device may obtain a standard parameter corresponding to a virtual scene in the simulation platform. The standard parameter may be a parameter that is estimated based on an assumption that the object to be tested is normal. The standard parameter may include at least one of a velocity, an acceleration, a moving direction, or a moving path. For example, the testing device may obtain information relating to the standard path based on a location of an obstacle in the virtual scene.

In some embodiments, the testing device may test the planned parameter based on the standard parameter. For example, in some embodiments, the testing device may obtain a second deviation value between the planned parameter and the standard parameter. If the second deviation value is greater than a second predetermined value, the testing device may determine that the planned parameter is abnormal. If the second deviation value is smaller than or equal to the second predetermined value, the testing device may determine that the planned parameter is normal. The process of determining the second deviation value may be similar to the process of determining the first deviation value described above in connection with FIG. 13.

In some embodiments, when the testing device tests the planned parameter, the testing device may determine whether the planned parameter matches with the virtual scene in which the virtual unmanned vehicle generated by the unmanned vehicle dynamic model simulation apparatus is currently located. If they match, the testing device may determine that the planned parameter is normal. If they do not match, the testing device may determine that the planned parameter is abnormal.

In some embodiments, the testing device may display the standard parameter and the planned parameter in real time, such that the user may analyze the standard parameter and the planned parameter to determine whether the planned parameter is normal. In some embodiments, the testing device may update, in real time, the standard parameter and the planned parameter as the testing time passes. In addition, for the viewing convenience of the user, the testing device may display the standard parameter and the planned parameter in different colors. If the testing device determines that the planned parameter is abnormal, the testing device may identify the planned parameter using a predetermined color and/or a predetermined identification. In some embodiments, the testing device may analyze the standard parameter and the planned parameter to determine an abnormal object that caused the abnormal planned parameter. The testing device may indicate the abnormal object to the user, such that the user may locate the point of failure.

In some embodiments, the testing device may record the display process of displaying the standard parameter and the planned parameter in a recording document. For example, a video file may be saved that records the process of displaying the standard parameter and the planned parameter, such that the user may playback the recording document.

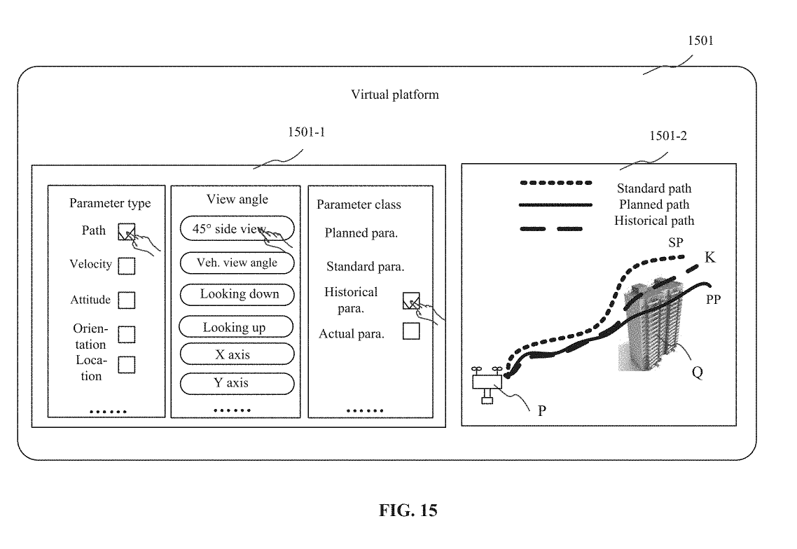

Next, the method of FIG. 14 is explained in detail using specific examples with reference to the path plot in FIG. 15.

FIG. 15 is a schematic interface for displaying a standard path and a planned path. The interface of FIG. 15 may include a function selection region 1501-1 and a parameter display region 1501-2. Although the interface is named a virtual platform 1501, the virtual platform may be part of the simulation platform included in other embodiments, or may be similar to the simulation platform.

The function selection region 1501-1 may include multiple function selection options. For example, the function selection region may include a parameter type selection zone, a view angle selection zone, and a parameter class selection zone.

A user may select, in the parameter type selection zone, a parameter type to be displayed in the parameter display region 1501-2. In some embodiments, the user may select multiple parameter types at the same time, such that parameters of the selected multiple parameter types may be displayed in the parameter display region 1501-2.

In some embodiments, the view angle selection zone may include multiple view angles to select, such as a 45 degree side view, an unmanned vehicle view angle (“Veh. view angle” in FIG. 15), a looking down angle, a looking up angle, etc. When the parameter type includes a vision parameter type, such as a path type, a user may select different view angles, such that different vision parameters corresponding to different view angles may be displayed in the parameter display region 1501-2.

In some embodiments, the parameter class selection zone may include planned parameter, standard parameter, actual parameter, and historical parameter. The planned parameter and the standard parameter may be fixedly selected items (i.e., selected by default), such that the parameter display region 1501-2 displays at least the planned parameter and the standard parameter. The user may select one or both of the historical parameter and the actual parameter, such that the parameter display zone 1501-2 displays the planned parameter and the standard parameter, as well as other selected parameters.

FIG. 15 only shows examples of the function selections that may be included in the function selection region 1501-1. Other functions may also be included in the function selection region 1501-1. The function selections to be included in the function selection region 1501-1 may be determined based on actual needs.

In the embodiment of FIG. 15, when testing the object to be tested, the virtual platform may display in real time the standard parameter and the planned parameter, and may update in real time the standard parameter and the planned parameter as time passes.

In the embodiment shown in FIG. 15, when the unmanned vehicle P is located at a present location shown in FIG. 15, the standard path SP for the unmanned vehicle P may be indicated by the dotted line. The testing device may determine, based on the virtual scene in which the unmanned vehicle P is located, that the planned path PP corresponding to the virtual scene is the path indicated by the solid line shown in FIG. 15.

In some embodiments, when the testing device determines that a difference between the standard path SP and the planned path PP is greater than a second predetermined value, the testing device may determine that the planned path PP is abnormal. In some embodiments, when the testing device may determine that the planned path PP does not match the virtual scene in which the unmanned vehicle is located (e.g., the planned path PP has a conflict with an obstacle Q), the testing device may determine that the planned path PP is abnormal.

Based on any of the above embodiments, the testing device may display to the user the planned parameter and the actual parameter in real time through the simulation platform, such that the user may analyze the object to be tested based on the planned parameter and the actual parameter. Thus, during the process of testing the object to be tested, through displaying in real time the planned parameter and the actual parameter, the user may observe in real time the operating process of the object to be tested. Accordingly, the user may determine the operating status of the object to be tested, thereby increasing the efficiency of testing the object to be tested.

In some embodiments, the testing device may obtain a historical parameter, and may display the planned parameter, the actual parameter, and the historical parameter through the simulation platform, such that a user may analyze the object to be tested based on the planned parameter, the actual parameter, and the historical parameter.

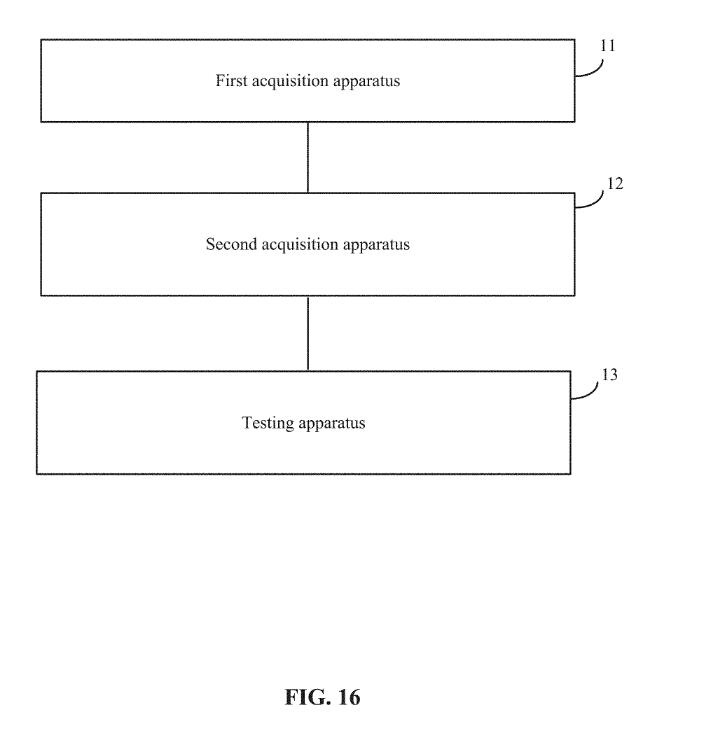

FIG. 16 is a schematic diagram of an object testing device. The object testing device of FIG. 16 may include:

A first acquisition apparatus 11 configured to obtain a planned parameter of the object to be tested.

A second acquisition apparatus 12 configured to obtain an actual parameter corresponding to the object to be tested through the simulation platform.

A testing apparatus 13 configured to determine a testing result corresponding to the object to be tested based on the planned parameter and the actual parameter.

The object testing device of the present disclosure may execute the above-described methods. The detailed descriptions of the operations of the object testing device can refer to the above descriptions of the embodiments of the methods and other embodiments of the testing device.

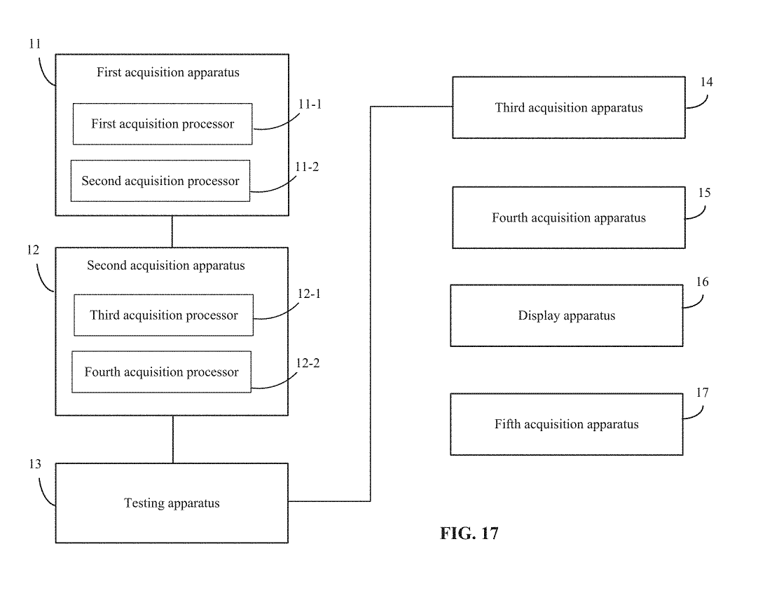

FIG. 17 is a schematic diagram of an object testing device. Based on the embodiment of FIG. 16, in the embodiment shown in FIG. 17, the first acquisition apparatus 11 may include a first acquisition processor 11-1 and a second acquisition processor 11-2.

The first acquisition processor 11-1 may be configured to obtain sensor data.

The second acquisition processor 11-2 may be configured to obtain the planned parameter based on the sensor data.

In some embodiments, the simulation platform may include a virtual sensor and a virtual scene. Correspondingly, the first acquisition processor 11-1 may be configured to obtain sensor data acquired by the virtual sensor from the virtual scene.

In some embodiments, the first acquisition processor 11-1 may be configured to receive sensor data from a physical sensor. The sensor data may be acquired by the physical sensor from an actual environment in which the physical sensor is located.

In some embodiments, the second acquisition processor 11-2 may be configured to process the sensor data based on the first pre-set object to obtain the planned parameter.

In some embodiments, the first pre-set object is provided in the unmanned vehicle.

In some embodiments, the first pre-set object is provided in a pre-set virtual model.

In some embodiments, the first pre-set object is provided in the simulation platform.

In some embodiments, the first pre-set object includes at least one of a vision object or a path planning object.

In some embodiments, the planned parameter includes at least one of a planned path, a planned velocity (including a planned angular velocity), a planned acceleration, or a planned distance.

In some embodiments, the second acquisition apparatus 12 may include a third acquisition processor 12-1 and a fourth acquisition processor 12-2.

In some embodiments, the third acquisition processor 12-1 may be configured to obtain the control command corresponding to the planned parameter.

In some embodiments, the fourth acquisition processor 12-2 may be configured to obtain the actual parameter based on the control command through the simulation platform.

In some embodiments, the third acquisition processor 12-1 may be configured to process the planned parameter based on the second pre-set object to obtain the control command.

In some embodiments, the second pre-set object is provided in the unmanned vehicle.

In some embodiments, the second pre-set object is provided in the pre-set virtual model.

In some embodiments, the second pre-set object is provided in the simulation platform.

In some embodiments, the control command includes a rotating speed and/or a rotating direction of at least one electric motor of the actual unmanned vehicle, or a rotating speed and/or a rotating direction of at least one electric motor of the virtual unmanned vehicle generated by the simulation platform.

In some embodiments, the third acquisition processor 12-1 may be configured to determine at least one electric motor corresponding to the planned parameter based on the type of the planned parameter; and determine a rotating speed and/or a rotating direction of the at least one electric motor based on the planned parameter.

In some embodiments, the fourth acquisition processor 12-2 may be configured to obtain the actual parameter based on the rotating speed and/or rotating direction of each electric motor and other operating parameters of each electric motor.

In some embodiments, the second pre-set object includes a control object.

In some embodiments, the object to be tested includes the first pre-set object and/or the second pre-set object.

In some embodiments, the testing apparatus 13 may be configured to obtain the first deviation value between the planned parameter and the actual parameter; determine that the testing result is abnormal when the first deviation value is greater than a first predetermined value; and determine that the testing result is normal when the first deviation value is smaller than or equal to the first predetermined value.

In some embodiments, the testing device may include a third acquisition apparatus 14.

In some embodiments, before the testing apparatus 13 determines the testing result corresponding to the object to be tested based on the planned parameter and the actual parameter, the third acquisition apparatus 14 may be configured to obtain at least one historical parameter corresponding to the object to be tested.

In some embodiments, correspondingly, the testing apparatus 13 may be configured to determine the testing result based on the planned parameter, the actual parameter, and the at least one historical parameter.

In some embodiments, the testing device may include a fourth acquisition apparatus 15.

In some embodiments, after the first acquisition apparatus 11 obtains the planned parameter corresponding to the object to be tested, the fourth acquisition apparatus 15 may be configured to obtain the standard parameter corresponding to the virtual scene of the simulation platform.

In some embodiments, the testing apparatus 13 may be configured to test the planned parameter based on the standard parameter.

In some embodiments, the testing apparatus 13 may be configured to obtain a second deviation value between the planned parameter and the standard parameter; determine that the planned parameter is abnormal if the second deviation value is greater than a second predetermined value; and determine that the planned parameter is normal if the second deviation value is smaller than or equal to the second predetermined value.

In some embodiments, the testing device may include a display apparatus 16.

The display apparatus 16 may be configured to display the planned parameter and the actual parameter after the second acquisition apparatus obtains the actual parameter corresponding to the object to be tested through the simulation platform, such that the user may analyze the object to be tested based on the planned parameter and the actual parameter.

In some embodiments, the testing device may include a fifth acquisition apparatus 17. The fifth acquisition apparatus 17 may be configured to obtain a historical parameter after the second acquisition apparatus obtains the actual parameter corresponding to the object to be tested through the simulation platform.

Correspondingly, the display apparatus 16 may be configured to display the planned parameter, the actual parameter, and the historical parameter, such that the user may analyze the object to be tested based on the planned parameter, the actual parameter, and the historical parameter.

In some embodiments, the sensor data include at least one of the following data: an image, a distance, a velocity (including an angular velocity), an acceleration, location coordinates data, and inertial data.

In some embodiments, the object to be tested may include an algorithm to be tested.

In some embodiments, the first pre-set object may include a first pre-set algorithm. Correspondingly, the vision object may include a vision algorithm, and the path planning object may include a path planning algorithm.

In some embodiments, the second pre-set object may include a second pre-set algorithm. Correspondingly, the control object may include a control algorithm.

The object testing device of the present disclosure may execute the steps of the disclosed methods.

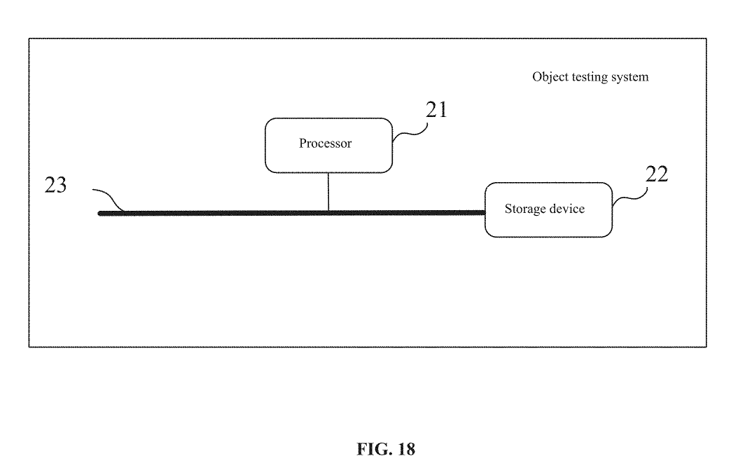

FIG. 18 is a schematic diagram of an object testing system. The system of FIG. 18 may include a processor 21, a storage device 22, and a communication bus 23. The storage device 22 may be configured to store computer program codes or instructions. The communication bus 23 may be configured to communicatively connect various components or units of the device. The processor 21 may be configured to retrieve or read the computer program codes or instructions stored in the storage device 22, and execute the codes or instructions to perform the disclosed methods, including the following processes:

obtaining a planned parameter corresponding to the object to be tested;

obtaining an actual parameter corresponding to the object to be tested through a simulation platform;

determining a testing result corresponding to the object to be tested based on the planned parameter and the actual parameter.

The object testing device of the present disclosure may execute steps of the methods disclosed herein.

In some embodiments, the processor 21 may be configured to obtain sensor data; and obtain the planned parameter based on the sensor data.

In some embodiments, the simulation platform may include a virtual sensor and a virtual scene. The processor 21 may be configured to obtain the sensor data acquired by the virtual sensor from the virtual scene.

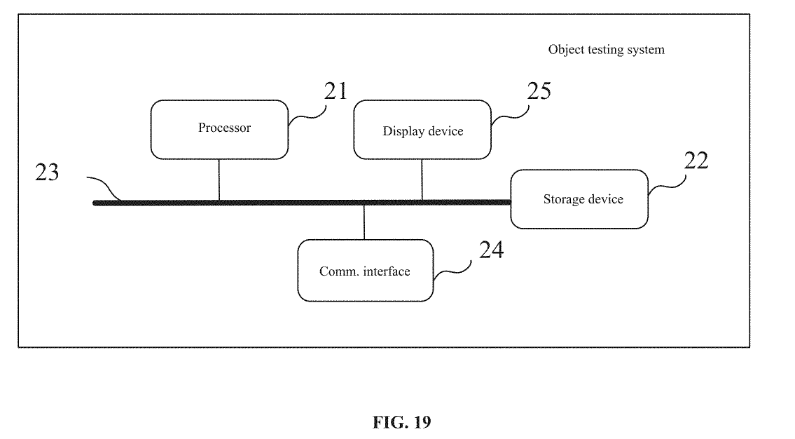

FIG. 19 is a schematic diagram of another object testing system. Based on the embodiments shown in FIG. 18, the object testing system of FIG. 19 may further include a communication interface 24. Correspondingly, the processor 21 may be configured to receive sensor data acquired by a physical sensor through the communication interface 24. The sensor data may be obtained by the physical sensor from the actual physical environment in which the physical sensor is located.

In some embodiments, the processor 21 may be configured to process the sensor data based on the first pre-set object to obtain the planned parameter.

In some embodiments, the first pre-set object may be provided in the unmanned vehicle.

In some embodiments, the first pre-set object may be provided in the pre-set virtual model.

In some embodiments, the first pre-set object may be provided in the simulation platform.

In some embodiments, the first pre-set object may include at least one of a vision object and a path planning object.

In some embodiments, the planned parameter may include at least one of a planned path, a planned velocity (including a planned angular velocity), a planned acceleration, or a planned distance.

In some embodiments, the processor 21 may be configured to obtain the control command corresponding to the planned parameter; and obtain the actual parameter based on the control command through the simulation platform.

In some embodiments, the processor 21 may be configured to process the planned parameter based on the second pre-set object to obtain the control command.

In some embodiments, the second pre-set object may be provided in the unmanned vehicle.

In some embodiments, the second pre-set object may be provided I the virtual model.

In some embodiments, the second pre-set object may be provided in the simulation platform.

In some embodiments, the control command may include at least one of the rotating speed and/or rotating direction of at least one actual electric motor, or the rotating speed and/or the rotating direction of at least one virtual electric motor included in the virtual unmanned vehicle generated by the simulation platform.

In some embodiments, the processor 21 may be configured to determine at least one electric motor corresponding to the planned parameter based on the type of the planned parameter; and determine the rotating speed and/or the rotating direction of the at least one electric motor based on the planned parameter.

In some embodiments, the processor 21 may be configured to obtain the actual parameter based on the rotating speed and/or the rotating direction of each electric motor and other parameters of each electric motor.

In some embodiments, the second pre-set object may include a control object.

In some embodiments, the object to be tested may include the first pre-set object and/or the second pre-set object.

In some embodiments, the processor 21 may be configured to obtain the first deviation value between the planned parameter and the actual parameter; determine that the testing result is abnormal if the first deviation value is greater than the first predetermined value; and determine that the testing result is normal if the first deviation value is smaller than or equal to the first predetermined value.

In some embodiments, before the processor 21 determines the testing result corresponding to the object to be tested based on the planned parameter and the actual parameter, the processor 21 may be configured to obtain at least one historical parameter corresponding to the object to be tested.

Correspondingly, the processor may be configured to determine the testing result based on the planned parameter, the actual parameter, and the at least one historical parameter.

In some embodiments, after the processor 21 obtains the planned parameter corresponding to the object to be tested, the processor 21 may be configured to obtain the standard parameter corresponding to the virtual scene in the simulation platform; and test the planned parameter based on the standard parameter.

In some embodiments, the processor 21 may be configured to obtain the second deviation value between the planned parameter and the standard parameter; determine that the planned parameter is abnormal if the second deviation value is greater than the second predetermined value; and determine that the planned parameter is normal if the second deviation value is smaller than or equal to the second predetermined value.

In some embodiments, the object testing system may include a display device 25.

In some embodiments, the display device 25 may be configured to display the planned parameter and the actual parameter after the processor 21 obtains the actual parameter corresponding to the object to be tested through the simulation platform, such that the user may analyze the object to be tested based on the planned parameter and the actual parameter.

In some embodiments, the processor 21 may be configured to obtain a historical parameter after the processors 21 obtains the actual parameter corresponding to the object to be tested through the simulation platform.

Correspondingly, the display device 25 may be configured to display the planned parameter, the actual parameter, and the historical parameter, such that the user may analyze the object to be tested based on the actual parameter and the historical parameter.

In some embodiments, the sensor data may include at least one of an image, a distance, a velocity (including an angular velocity), an acceleration, location coordinates data, and inertial data.

In some embodiments, the object to be tested may include an algorithm to be tested.

In some embodiments, the first pre-set object may include a first pre-set algorithm. Correspondingly, the vision object may include a vision algorithm, and the path planning object may include a path planning algorithm.

In some embodiments, the second pre-set object may include a second pre-set algorithm. Correspondingly, the control object may include a control algorithm.

The object testing device or system of the present disclosure may be configured to execute the various steps of the disclosed methods.

A person having ordinary skill in the art can appreciate that units and algorithms of the disclosed methods and processes may be implemented using electrical hardware, or a combination of electrical hardware and computer software. Whether the implementation is through hardware or software is to be determined based on specific application and design constraints. The computer software may be stored in a computer-readable medium as instructions or codes, such as a non-transitory computer-readable storage medium. The computer software, when executed by a computing device (e.g., a personal computer, a server, or a network device, etc.) or a processor, the computing device or processor may perform all or some of the steps of the disclosed methods. The non-transitory computer-readable storage medium can be any medium that can store program codes, for example, a read-only memory (“ROM”), a random-access memory (“RAM”), a magnetic disk, an optical disk, etc.

Other embodiments of the present disclosure will be apparent to those skilled in the art from consideration of the specification and practice of the embodiments disclosed herein. It is intended that the specification and examples be considered as example only and not to limit the scope of the present disclosure, with a true scope and spirit of the invention being indicated by the following claims. Variations or equivalents derived from the disclosed embodiments also fall within the scope of the present disclosure.

What is claimed is:

1. A method for testing an object to be tested, comprising:
obtaining a planned parameter corresponding to the object to be tested;
obtaining an actual parameter corresponding to the object to be tested through a simulation platform; and
obtaining a testing result corresponding to the object to be tested based on the planned parameter and the actual parameter.

2. The method of claim 1, wherein obtaining the planned parameter corresponding to the object to be tested comprises:
obtaining sensor data; and
obtaining the planned parameter based on the sensor data.

3. The method of claim 2, wherein
obtaining the planned parameter based on the sensor data comprises processing the sensor data based on a first pre-set object to obtain the planned parameter, and
the first pre-set object is provided in an unmanned vehicle.

4. The method of claim 3, wherein
the first pre-set object comprises at least one of a vision object or a path planning object, and
the planned parameter comprises at least one of a planned path, a planned velocity, a planned acceleration, or a planned distance.

5. The method of claim 4, wherein obtaining the actual parameter corresponding to the object to be tested through the simulation platform comprises:
obtaining a control command corresponding to the planned parameter; and
obtaining the actual parameter based on the control command through the simulation platform.

6. The method of claim 5, wherein obtaining the control command corresponding to the planned parameter comprises:
processing the planned parameter based on a second pre-set object to obtain the control command.

7. The method of claim 6, wherein the second pre-set object is provided in an unmanned vehicle.

8. The method of claim 6, wherein the second pre-set object is provided in the simulation platform.

9. The method of claim 6, wherein
the control command comprises at least one of:
a rotating speed and/or a rotating direction of at least one physical electric motor included in a physical unmanned vehicle, or
a rotating speed and/or a rotating direction of at least one virtual electric motor included in a virtual unmanned vehicle generated by the simulation platform, and
processing the planned parameter based on the second pre-set object to obtain the control command comprises:
determining at least one physical or virtual electric motor corresponding to the planned parameter based on a type of the planned parameter; and
determining at least one of the rotating speed or the rotating direction of each of the at least one physical or virtual electric motor based on the planned parameter.

10. The method of claim 9, wherein obtaining the actual parameter based on the control command comprises:
obtaining the actual parameter based on at least one of the rotating speed, the rotating direction, or an operating parameter of each of the at least one physical or virtual electric motor.

11. The method of claim 6, wherein the second pre-set object comprises a control object.

12. The method of claim 6, wherein the object to be tested comprises at least one of the first pre-set object or the second pre-set object.

13. The method of claim 6, wherein
the first pre-set object comprises a first pre-set algorithm, the vision object comprises a vision algorithm, and the path planning object comprises a path planning algorithm, and
the second pre-set object comprises a second pre-set algorithm, and the control object comprises a control algorithm.

14. The method of claim 2, wherein the sensor data comprise at least one of an image, a distance, a velocity, an acceleration, location coordinates data, or inertial data.

15. The method of claim 1, wherein determining the testing result corresponding to the object to be tested based on the planned parameter and the actual parameter comprises:
obtaining a first deviation value between the planned parameter and the actual parameter;
determining that the testing result is abnormal if the first deviation value is greater than a first predetermined value; and
determining that the testing result is normal if the first deviation value is smaller than or equal to the first predetermined value.

16. The method of claim 1, further comprising:
after obtaining the actual parameter corresponding to the object to be tested through the simulation platform, displaying the planned parameter and the actual parameter to a user for the user to analyze the object to be tested based on the planned parameter and the actual parameter.

17. The method of claim 1, further comprising:
after obtaining the actual parameter corresponding to the object to be tested through the simulation platform, obtaining a historical parameter; and
displaying the planned parameter, the actual parameter, and the historical parameter to a user for the user to analyze the object to be tested based on the planned parameter, the actual parameter, and the historical parameter.

18. The method of claim 1, wherein the object to be tested comprises an algorithm to be tested.

19. A device for testing an object to be tested, comprising:
a first acquisition apparatus configured to obtain a planned parameter corresponding to the object to be tested;
a second acquisition apparatus configured to obtain an actual parameter corresponding to the object to be tested through a simulation platform; and
a testing apparatus configured to determine a testing result corresponding to the object to be tested based on the planned parameter and the actual parameter.

20. A system for testing an object to be tested, comprising:
a storage device configured to store instructions; and
a processor configured to retrieve the instructions and execute the instructions to:
obtain a planned parameter corresponding to the object to be tested;
obtain an actual parameter corresponding to the object to be tested through a simulation platform; and
determine a testing result corresponding to the object to be tested based on the planned parameter and the actual parameter.
